(19) United States
(12) Patent Application Publication
(10) Pub. No.: US 2008/0122033 A1
(43) Pub. Date: May 29, 2008

(54) Semiconductor device and manufacturing the same

(75) Inventors: Keun-Bong Lee, Yongin-si (KR); Jung-Hyeon Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/986,896

(22) Filed: Nov. 27, 2007

(30) Foreign Application Priority Data
Nov. 29, 2006 (KR) 10-2006-0119192

(51) Int. Cl. H01L 29/92; H01L 21/02

(52) U.S. Cl. 257/532; 438/396; 257/E21.011; 257/E29.343

(57) ABSTRACT

In a semiconductor device and a method of manufacturing the semiconductor device, an electric element is formed. A first insulation interlayer is formed on the electric element. A capacitor structure is formed on the first insulation interlayer. The capacitor structure vertically disposed relative to the electric element. The capacitor structure has a shape extending horizontally. Thus, a space under the capacitor structure having a relatively large area can be utilized for increasing an integration degree of the semiconductor device. Accordingly, the size of a semiconductor chip including the semiconductor device can be reduced.

### CROSS-REFERENCE TO RELATED APPLICATIONS

This application claims priority under 35 U.S.C. § 119 to Korean Patent Application No. 10-2006-0119192, filed on Nov. 29, 2006 in the Korean Intellectual Property Office (KIPO), the disclosure of which is incorporated herein by reference in its entirety.

### BACKGROUND OF THE INVENTION

1. Field of the Invention

The present invention relates to a semiconductor device and a method of manufacturing the semiconductor device. More particularly, the present invention relates to a semiconductor device having a capacitor structure occupying a relatively large area and a method of manufacturing the semiconductor device.

2. Description of the Related Art

Semiconductor devices are generally manufactured through a fabrication (FAB) process for forming integrated circuits on a substrate, an electrical die sorting (EDS) process for inspecting electrical characteristics of the integrated circuits, and a packaging process for separating individual semiconductor devices.

The FAB process includes various unit processes. For example, various unit processes such as a photolithography process and an etching process can be used to form a capacitor.

Generally, the capacitor can be classified as a cylindrical capacitor, a metal-insulator-metal (MIM) capacitor, or a vertical parallel plate (VPP) capacitor.

Examples of conventional cylindrical capacitors are disclosed in Korean Patent Application Laid-Open Publication Nos. 2006-35473, 2005-100107, and 2005-20232. The cylindrical capacitor has a shape extending vertically. Thus, an area occupied by the cylindrical capacitor is relatively small. Accordingly, when forming a semiconductor chip including a semiconductor device in which the cylindrical capacitor is employed, the relatively large number of semiconductor chips can be produced from one wafer.

Examples of conventional MIM capacitors are disclosed in Korean Patent Laid-Open Publication Nos. 2006-68036, 2004-40105 and 2003-48226. In addition, examples of conventional VPP capacitors are disclosed in Korean Patent Laid-Open Publication No. 2006-72412 and U.S. Patent Laid-Open Publication No. 2006-0157770.

Particularly, the MIM capacitor has a shape extending horizontally. In addition, the VPP capacitor has a shape extending horizontally and vertically. That is, the MIM capacitor and the VPP capacitor extend horizontally.

Thus, an area occupied by the MIM capacitor or the VPP capacitor is relatively large compared to an area occupied by the cylindrical capacitor. In addition, an electric element is not formed under the MIM capacitor or the VPP capacitor included in a recent semiconductor device. Thus, the size of the recent semiconductor device can increase according to the area occupied by the MIM capacitor or the VPP capacitor.

Thus, in case that the MIM capacitor or the VPP capacitor is employed in the semiconductor device, the size of the semiconductor chip including the semiconductor device can increase. As a result, the number of semiconductor chips produced from one wafer can decrease. In addition, the yield and productivity of the semiconductor chips can decrease.

### SUMMARY OF THE INVENTION

In accordance with the present invention there is provided a semiconductor device capable of reducing the size of a semiconductor chip.

Also in accordance with the present invention there is provided a method of manufacturing the semiconductor device.

In accordance with an aspect of the present invention, a semiconductor device is provided. The semiconductor includes an electric element, a first insulation interlayer, and a capacitor structure. The first insulation interlayer is provided on the electric element. The capacitor structure is provided on the first insulation interlayer. The capacitor structure is vertically disposed relative to the electric element. The capacitor structure has a shape extending horizontally.

The electric element can be a resistance element, a diode element, an inductor element, or a transistor element.

The semiconductor device can further include a protective layer and a second insulation interlayer. The protective layer can be provided on the first insulation interlayer, the protective layer including a conductive material. The second insulation interlayer can be provided between the protective layer and the capacitor structure.

In the above case, the protective layer can be grounded.

The capacitor structure can include conductive structures, contact structures and an insulation structure. The conductive structures can be spaced apart from one another in a first direction. The contact structures can be provided on the conductive structures. The conductive structures and the contact structures can be repeatedly stacked. The insulation structure can fill up spaces between the conductive structures and the contact structures.

The capacitor structure can include a lower electrode, a dielectric layer, and an upper electrode. The lower and upper electrodes can have substantially plate shapes. The lower and upper electrodes can vertically correspond to each other. The dielectric layer can be provided between the lower and upper electrodes.

The electric element can be a resistance element. The resistance element can be provided on an isolation layer formed at an upper portion of a semiconductor substrate. The resistance element can include polysilicon doped with impurities.

Here, the semiconductor device can further include an insulation layer, a contact, and a conductive wire. The insulation layer pattern can be provided on the semiconductor substrate to cover the resistance element and the isolation layer. The insulation layer pattern can have a hole exposing an end portion of the resistance element. The contact can be provided in the hole. The conductive wire can be provided on the insulation layer pattern to be connected to the contact. The first insulation interlayer can be provided on the insulation layer pattern to cover the conductive wire.

In accordance with another aspect of the present invention, there is provided a method of manufacturing a semiconductor device. In the method, an electric element is formed. A first insulation interlayer is formed on the electric element. A capacitor structure is formed on the first insulation interlayer. The capacitor structure is disposed vertically relative to the electric element. The capacitor structure has a shape extending horizontally.

The electric element can be a resistance element, a diode element, an inductor element or a transistor element.

To manufacture the semiconductor device, a protective layer and a second insulation interlayer can be further formed. The protective layer can be formed on the first insulation interlayer by using a conductive material. The second insulation interlayer can be formed between the protective layer and the capacitor structure.

The protective layer can be grounded.

To form the capacitor structure, conductive structures spaced apart from one another in a first direction can be formed. A first insulation film can be formed between the conductive structures. A second insulation film can be formed on the conductive structures and the first insulation films. The second insulation film can have holes exposing the conductive structures. Contact structures can be formed in the holes of the second insulation film.

Here, the forming of the conductive structures, the forming of the first insulation film, the forming of the second insulation film and the forming of the contact structures can be repeatedly performed such that the conductive structures make vertical contact with the contact structures.

To form the capacitor structure, a lower electrode having a substantially plate shape can be formed. A dielectric layer can be formed on the lower electrode. An upper electrode can be formed on the dielectric layer. The upper electrode can vertically correspond to the lower electrode. The upper electrode can have a substantially plate shape.

The electric element can be a resistance element. In this case, in order to form the electric element, an isolation layer can be formed at an upper portion of a semiconductor substrate. A polysilicon layer doped with impurities can be formed on the isolation layer. The polysilicon layer can be transformed into the electric element on the isolation layer by performing a patterning process.

Particularly, an insulation layer can be formed on the semiconductor substrate to cover the resistance element and the isolation layer. A contact can be formed through the insulation layer to be electrically connected to an end portion of the resistance element. A conductive wire can be formed on the insulation layer to be connected to the contact. The first insulation interlayer can be formed on the insulting layer pattern to cover the conductive wire.

According to aspects of the present invention, a space under a capacitor structure having a relatively wide area can be utilized for increasing an integration degree of a semiconductor device. Thus, the size of a semiconductor chip including the semiconductor device can be reduced.

In case that the size of the semiconductor chip is reduced, the number of semiconductor chips produced from one wafer can increase. Thus, the yield and productivity of the semiconductor chip can increase.

### BRIEF DESCRIPTION OF THE DRAWINGS

The above and other advantages of the present invention will become readily apparent with reference to the following detailed description when considered in conjunction with the accompanying drawings, in which:

FIG. 1 is a cross-sectional view illustrating an embodiment of a semiconductor device in accordance with an aspect of the present invention;

FIGS. 2 to 8 are cross-sectional views illustrating an embodiment of a method of manufacturing the semiconductor device in FIG. 1;

FIG. 9 is a cross-sectional view illustrating an embodiment of a semiconductor device in accordance with another aspect of the present invention;

FIGS. 10 and 11 are cross-sectional views illustrating an embodiment of a method of manufacturing the semiconductor device in FIG. 9;

FIG. 12 is a cross-sectional view illustrating an embodiment of a semiconductor device in accordance with another aspect of the present invention;

FIGS. 13 and 14 are cross-sectional views illustrating an embodiment of a method of manufacturing the semiconductor device in FIG. 12;

FIG. 15 is a cross-sectional view illustrating an embodiment of a semiconductor device in accordance with another aspect of the present invention; and

FIGS. 16 and 17 are cross-sectional views illustrating an embodiment of a method of manufacturing the semiconductor device in FIG. 15.

### DESCRIPTION OF THE EMBODIMENTS

Embodiments in accordance with aspects of the present invention will be described with reference to the accompanying drawings. The present invention can, however, be embodied in many different forms and should not be construed as limited to the embodiments set forth herein. The principles and features of this invention can be employed in varied and numerous embodiments without departing from the scope of the present invention. In the drawings, the size and relative sizes of layers and regions may be exaggerated for clarity. The drawings are not necessarily to scale. Like reference numerals designate like elements throughout the drawings.

It will also be understood that when an element or layer is referred to as being “on,” “connected to” and/or “coupled to” another element or layer, the element or layer can be directly on, connected and/or coupled to the other element or layer or intervening elements or layers can be present. In contrast, when an element is referred to as being “directly on,” “directly connected to” and/or “directly coupled to” another element or layer, no intervening elements or layers are present. As used herein, the term “and/or” can include any and all combinations of one or more of the associated listed items.

It will also be understood that, although the terms first, second, etc. may be used herein to describe various elements, components, regions, layers and/or sections. These elements, components, regions, layers and/or sections should not be limited by these terms. These terms can be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device can be otherwise oriented (e.g., rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof.

Embodiments in accordance with aspect of the present invention are described with reference to cross-section illustrations that are schematic illustrations of idealized embodiments. As such, variations from the shapes of the illustrations as a result, for example, of manufacturing techniques and/or tolerances, are to be expected. Thus, embodiments provided herein should not be construed as limited to the particular shapes of regions illustrated herein, but are to include deviations in shapes that result, for example, from manufacturing. For example, a region illustrated as a rectangle will, typically, have rounded or curved features. Thus, the regions illustrated in the figures are schematic in nature of a device and are not intended to limit the scope of the present invention.

FIG. 1 is a cross-sectional view illustrating an embodiment of a semiconductor device in accordance with an aspect of the present invention.

Referring to FIG. 1, a semiconductor device 10 can include an electric element and a capacitor structure 190. The electric element can be a resistance element 125. Particularly, the resistance element 125 can be provided on an isolation layer 110 formed at an upper portion of the semiconductor substrate 100.

Here, the semiconductor substrate 100 can be a silicon substrate, a silicon germanium substrate, or a silicon-on-insulator substrate. The isolation layer 110 can fill up a trench formed at the upper portion of the semiconductor substrate 100. The isolation layer 110 can include an insulation material, such as, e.g., silicon oxide.

The resistance element 125 can include polysilicon. In addition, the resistance element 125 can be doped with n-type (negative-typed) impurities, such as nitrogen (N) or phosphorus (P). The n-type impurities can provide the resistance element 125 with electrons. Alternatively, the resistance element 125 can be doped with p-type (positive-typed) impurities, such as boron (B), gallium (Ga) or indium (In). The p-type impurities can provide the resistance element 125 with holes.

An insulation layer pattern 135 is formed on the semiconductor substrate 100 to cover the resistance element 125 and the isolation layer 110. The insulation layer pattern 135 can include an insulation material, such as silicon oxide or silicon nitride. In addition, the insulation layer pattern 135 can have at least one hole 13 exposing the resistance element 125. The hole 13 can be adjacent to an end portion of the resistance element 125.

A contact is provided in the hole 13. For example, the contact 140 can include a metal such as copper (Cu) or tungsten (W), as examples. A conductive wire 150 is provided on the insulation layer pattern 135 such that the conductive wire 150 is connected to the contact 140. For example, the conductive wire 150 can include a metal such as, e.g., copper or tungsten.

As illustrated in FIG. 1, the contact 140 and the conductive wire 150 can vertically correspond to the end portion of the resistance element 125. Thus, the contact 140 and the conductive wire 150 need not be formed on a portion of the insulation layer pattern 135 vertically corresponding to a central portion of the resistance element 125.

A first insulation interlayer 160 is provided on the insulation layer pattern 135 to cover the conductive wire 150. The first insulation interlayer 160 can include an insulation material, such as silicon oxide or silicon nitride.

A capacitor structure 190 including conductive structures 170, contact structures 180 and an insulation structure 185 can be provided on a portion of the first insulation interlayer 160 vertically corresponding to the central portion of the resistance element 125.

The conductive structures 170 can be spaced apart from one another in a first direction on the portion of the first insulation interlayer 160 vertically corresponding to the central portion of the resistance element 125. Thus, the conductive structure 170 can have a shape extending horizontally, e.g., in the first direction.

The contact structure 180 can be provided on the conductive structure 170. As illustrated in FIG. 1, the conductive structure 170 and the contact structure 180 can be alternately and repeatedly stacked.

A space between horizontally adjacent conductive structures 170 and a space between horizontally adjacent contact structures 180 are filled with the insulation structure 185. For example, the insulation structure 185 can include a material having a relatively high dielectric constant.

Particularly, the conductive structure 170 and the contact structure 180 can face each other, while being arranged in the first direction. As described above, the space between the horizontally adjacent conductive structures 170 and the horizontally adjacent contact structures 180 are filled with the insulation structure 185. Thus, a plurality of capacitors is formed in the first direction.

The resistance element 125 is used as the electric element in the present embodiment. However, various kinds of electric elements can be used instead of the resistance element 125. As one example, a diode element can be used instead of the resistance element 125. As another example, an inductor element can be used instead of the resistance element 125. As still another example, a transistor element can be used instead of the resistance element 125.

Hereinafter, an embodiment of a method of manufacturing the semiconductor device in FIG. 1 is described.

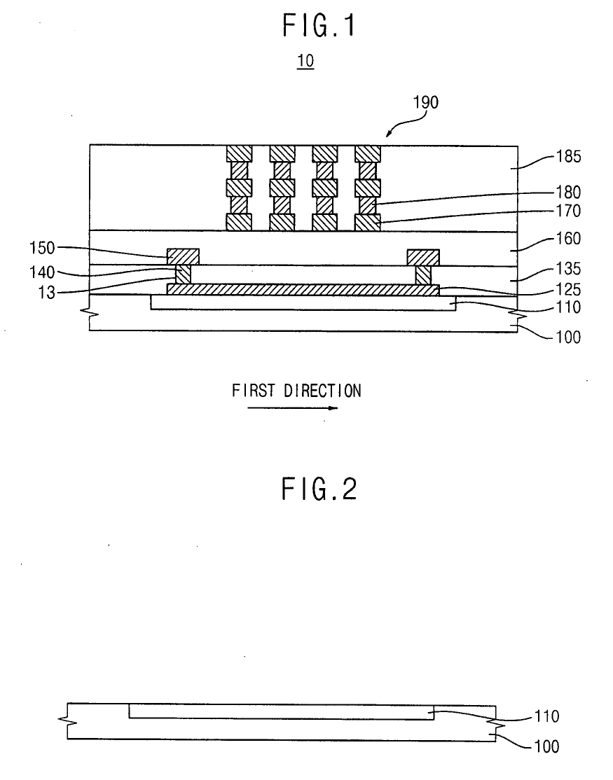

Specifically, FIGS. 2 to 8 are cross-sectional views illustrating a method of manufacturing the semiconductor structure in FIG. 1.

Referring to FIG. 2, a semiconductor substrate 100 is provided. The semiconductor substrate 100 can be a silicon substrate, a silicon germanium substrate, or a silicon-on-insulator substrate. A trench is formed at an upper portion of the semiconductor substrate 100. An isolation layer 110 filling up the trench is then formed using an insulation material, such as silicon oxide. Thus, an isolation layer 110 is formed at the upper portion of the semiconductor substrate 100.

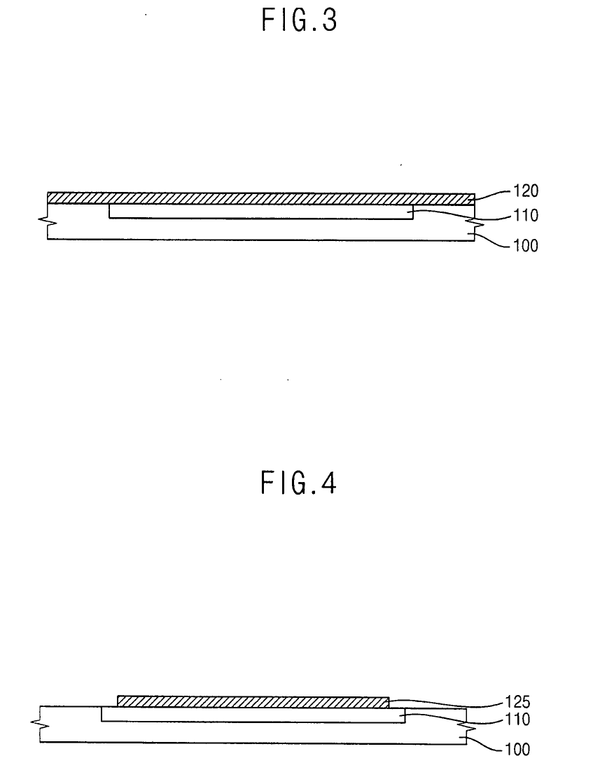

Referring to FIG. 3, a polysilicon layer 120 is formed on the semiconductor substrate 100 where the isolation layer 110 is formed. The polysilicon layer 120 can be doped with impurities. As one example, the polysilicon layer 120 can be doped with n-type impurities, such as nitrogen and phosphorus. The n-type impurities can provide the polysilicon layer 120 with electrons. As another example, the polysilicon layer 120 can be doped with p-type impurities, such as boron, gallium and indium. The p-type impurities can provide the polysilicon layer 120 with holes.

Referring to FIG. 4, a photolithography process is performed on the polysilicon layer 120 to transform the polysilicon layer 120 into a resistance element 125. Particularly, the resistance element 125 can be formed on the isolation layer 110.

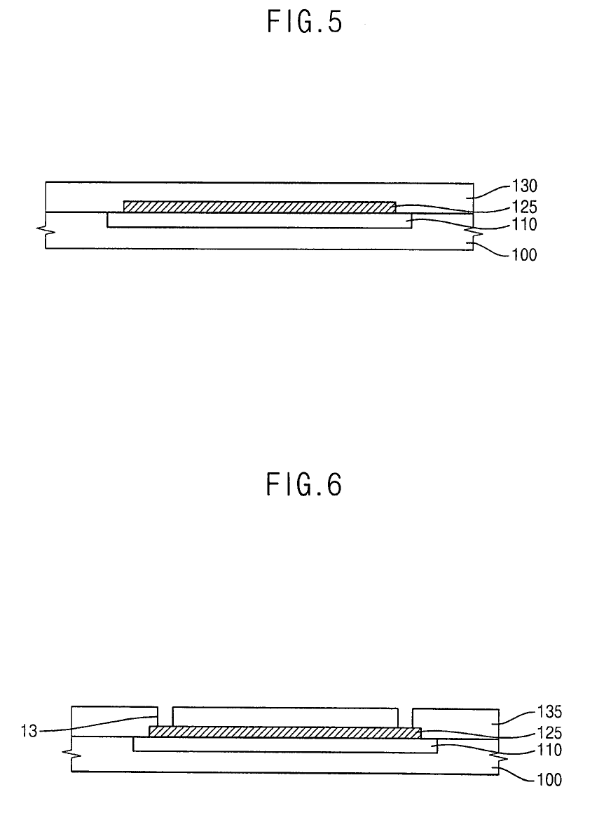

Referring to FIG. 5, an insulation layer 130 is formed on the semiconductor substrate 100 to cover the resistance element 125 and the isolation layer 110. The insulation layer 130 can be formed using an insulation material, such as silicon oxide or silicon nitride.

Referring to FIG. 6, a photolithography process is performed on the insulation layer 130 to transform the insulation layer 130 into an insulation layer pattern 135. The insulation layer pattern 135 can have at least one hole 13 exposing the resistance element 125. The hole 13 can be adjacent to an end portion of the resistance element 125.

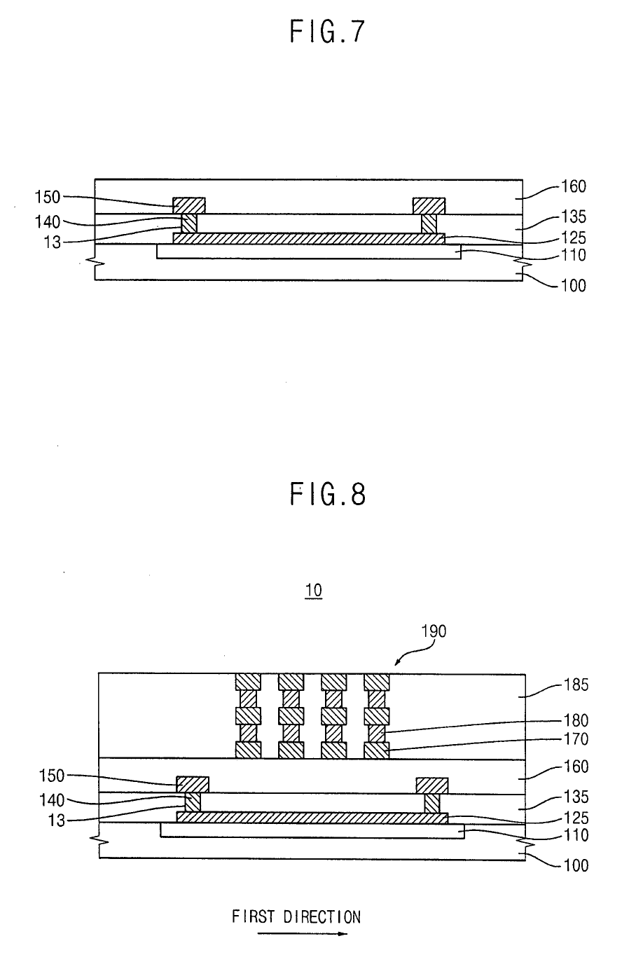

Referring to FIG. 7, a contact 140 filling up the hole 13 is formed. Particularly, a conductive layer filling up the hole 13 is formed on the insulation layer pattern 135. A planarization process, such as a chemical mechanical polishing (CMP) process or an etch-back process, can then be performed on the conductive layer until the insulation layer pattern 135 is exposed so that the contact 140 can be formed in the hole 13. For example, the contact 140 can include a metal, such as copper or tungsten.

A conductive wire 150 is formed on the insulation layer pattern 135 such that the conductive wire 150 is connected to the contact 140. Particularly, a conductive layer is formed on the insulation layer pattern 135.

A patterning process, such as a photolithography process, is then performed on the conductive layer to form the conductive wire connected to the contact 140. For example, the conductive wire 150 can include a metal, such as copper or tungsten.

As illustrated in FIG. 7, the contact 140 and the conductive wire 150 vertically correspond to an end portion of the resistance element 125. Thus, the contact 140 and the conductive wire 150 need not be formed on a portion of the insulation layer pattern 135 vertically corresponding to a central portion of the resistance element 125.

A first insulation interlayer 160 is formed on the insulation layer pattern 135 to cover the conductive wire 150. The first insulation interlayer 160 can be formed using an insulation material, such as silicon oxide or silicon nitride.

Referring to FIG. 8, a capacitor structure 190 including conductive structures 170, contact structures 180, and an insulation structure 185 is formed on a portion of the first insulation interlayer 160 vertically corresponding to the central portion of the resistance element 125.

Particularly, the conductive structures 170 are formed on the portion of the first insulation interlayer 160 corresponding to the central portion of the resistance element 125 such that the conductive structures 170 are spaced apart from one another in a first direction. The capacitor structure 190 can have a shape extending horizontally because the conductive structures 170 are spaced apart from one another in the first direction.

A first insulation film is formed at a space between the conductive structures 170. A second insulation film is then formed on the first insulation film. The second insulation film can have a hole exposing the conductive structure 170. Thereafter, the contact structure 180 is formed in the hole formed through the second insulation film. Another conductive structure electrically connected to the contact structure 180 is then formed on the contact structure 180 and the second insulation film.

A process of forming the conductive structure 170, a process of forming the first insulation film, a process of forming the second insulation film, and a process of forming a contact structure 180 are subsequently and repeatedly performed to form the capacitor structure 190.

Thus, as illustrated in FIG. 1, the conductive structure 170 and the contact structure 180 can be alternately and repeatedly stacked. In addition, the insulation structure 185 can include the first and second insulation films alternately and repeatedly stacked.

Particularly, the conductive structure 170 and the contact structure 180 can face each other, while being arranged in the first direction. In addition, a space between horizontally adjacent conductive structures 170 and a space between horizontally adjacent contact structures 180 can be filled with the insulation structure 185. Thus, a plurality of capacitors can be formed in the first direction.

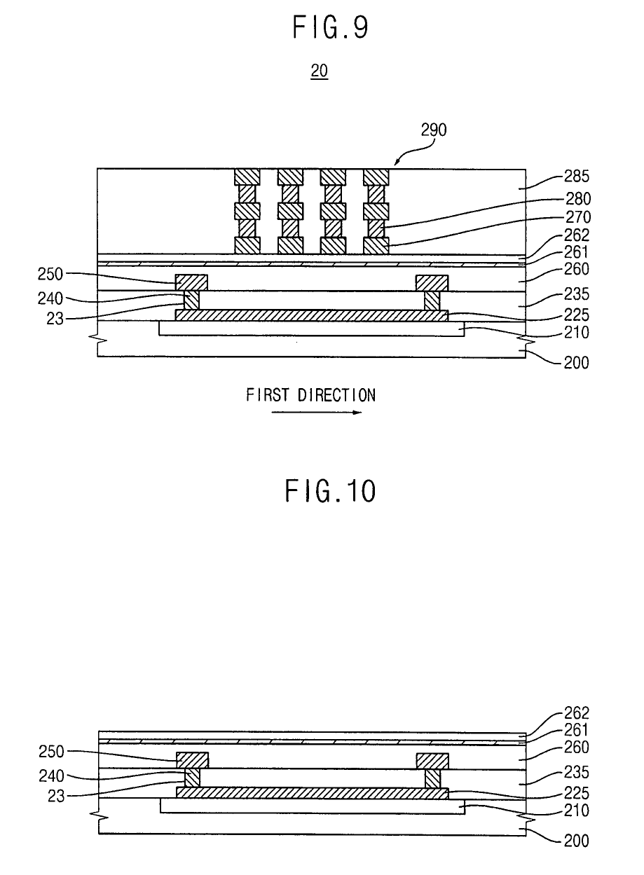

FIG. 9 is a cross-sectional view illustrating an embodiment of a semiconductor device in accordance with another aspect of the present invention.

Referring to FIG. 9, a semiconductor device 20 is substantially the same as the semiconductor device 10 in FIG. 1 except for a protective layer 261 and a second insulation interlayer 262. Thus, a repetitive explanation will be omitted.

A protective layer 261 having a relatively thin thickness is provided on a first insulation interlayer 260. The protective layer 261 can include a conductive material, such as a metal. In addition, the protective layer 261 can be grounded. A second insulation interlayer 262 can be provided on the protective layer 261. The second insulation interlayer 262 can include an insulation material, such as silicon oxide or silicon nitride.

A capacitor structure 290 including conductive structures 270 and contact structures 280 can be provided on a portion of the second insulation interlayer 262 vertically corresponding to a central portion of the resistance element 225.

The protective layer 261 is provided between the resistance element 225 and the capacitor structure 290 in the present embodiment. The protective layer 261 can reduce signal interference generated between the resistance element 225 and the capacitor structure 290. Thus, operation characteristics of the semiconductor device 20 can be improved.

Hereinafter, an embodiment of a method of manufacturing the semiconductor device 20 in FIG. 9 is described.

Specifically, FIGS. 10 and 11 are cross-sectional views illustrating a method of manufacturing the semiconductor device in FIG. 9.

Referring to FIG. 10, an isolation layer 210, a resistance element 225, an insulation layer pattern 235, a contact 240 and a conductive wire 250 and a first insulation interlayer 260 are formed on a semiconductor substrate 200. The insulation layer pattern 235 has a hole 23 formed therein. The contact 240 fills up the hole 23. The conductive wire 250 is formed on the contact 240 and the insulation layer pattern 235 such that the conductive wire 250 is connected to the contact 240. The first insulation interlayer 260 is formed on the insulation layer pattern 235 to cover the conductive wire 250.

Processes of forming the semiconductor substrate 200, the isolation layer 210, the resistance element 225, the insulation layer pattern 235, the contact 240, the conductive pattern 250 and the first insulation interlayer 260 are substantially the same as processes in FIGS. 2 to 7. Thus, any further explanation will be omitted.

Referring again to FIG. 10, a protective layer 261 having a relatively thin thickness is formed on the first insulation interlayer 260. The protective layer 261 can be formed using a conductive material, such as a metal.

Thereafter, a second insulation interlayer 262 is formed on the protective layer 261. The second insulation interlayer 262 can be formed using an insulation material, such as silicon oxide or silicon nitride.

Referring to FIG. 11, a capacitor structure 290 including conductive structures 270 and contact structures 280 is formed on a portion of the second insulation interlayer 262 vertically corresponding to a central portion of the resistance element 225. Processes of forming the capacitor structure 290 are substantially the same as processes of forming the capacitor structure 190 in FIG. 8. Thus, any further explanation will be omitted.

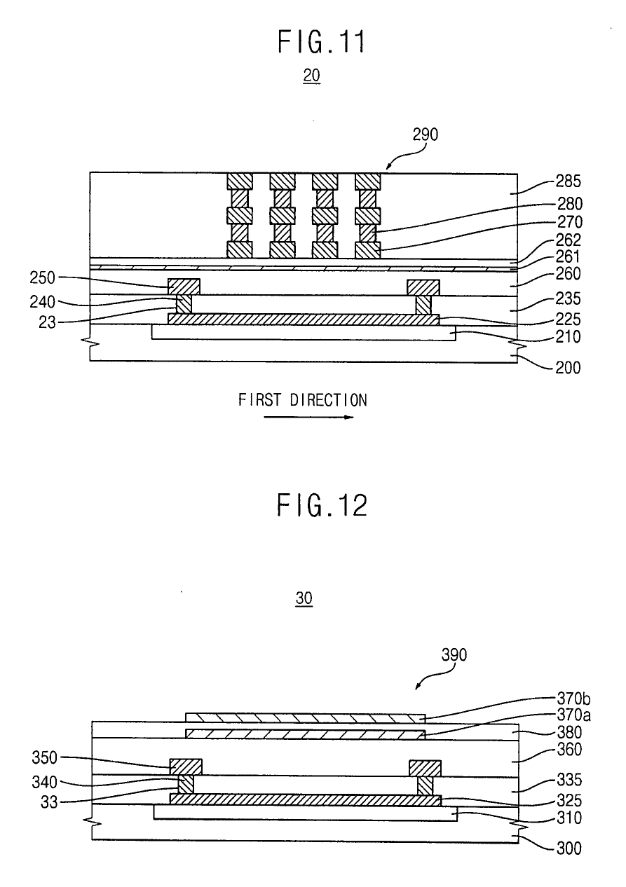

FIG. 12 is a cross-sectional view illustrating another embodiment of a semiconductor device in accordance with another aspect of the present invention.

Referring to FIG. 12, a semiconductor device 30 is substantially the same as the semiconductor device 10 in FIG. 1 except for the capacitor structure 390. Thus, a repetitive explanation will be omitted.

The capacitor structure 390 can include a lower electrode 370a, a dielectric layer 380 and an upper electrode 370b. Particularly, the lower electrode 370a is provided on a portion of a first insulation interlayer 360 vertically corresponding to the resistance element 325. Although not particularly illustrated in FIG. 12, the lower electrode 370a can have a substantially plate shape. The lower electrode 370a can include a conductive material, such as a metal.

The dielectric layer 380 is provided on the first insulation interlayer 360 to cover the lower electrode 370a. The dielectric layer 380 can include a material having a relatively high dielectric constant. The upper electrode 370b is provided on the dielectric layer 380. Particularly, the upper electrode 370b can vertically correspond to the lower electrode 370a. Although not particularly illustrated in FIG. 12, the upper electrode 370b can have a substantially plate shape. The upper electrode 370b can include a conductive material, such as a metal.

As described above, the lower electrode 370a and the upper electrode 370b can have the substantially plate shapes. Thus, the capacitor structure 390 can have a shape extending horizontally.

Hereinafter, an embodiment of a method of forming the semiconductor device in FIG. 12 is described.

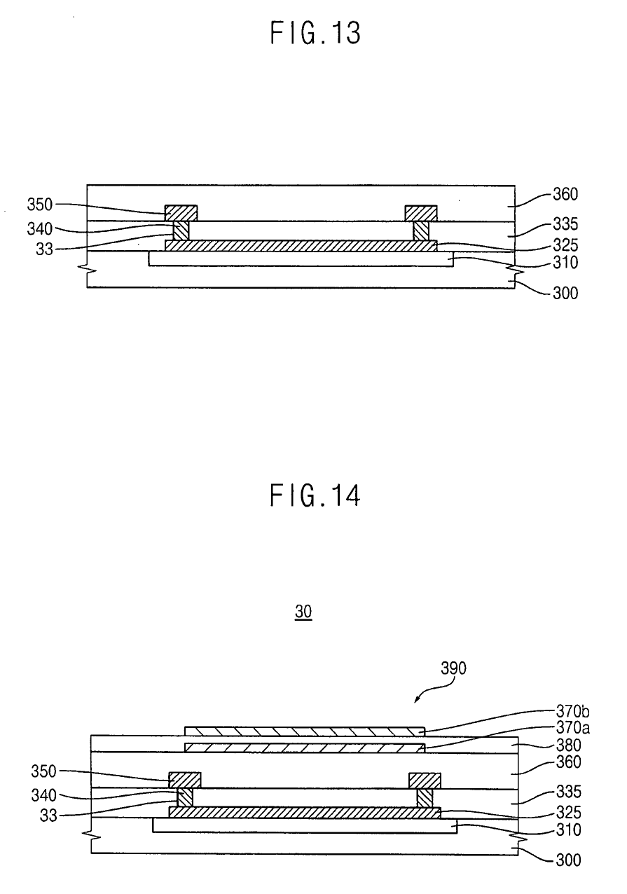

Specifically, FIGS. 13 to 14 are cross-sectional views illustrating a method of manufacturing the semiconductor device in FIG. 12.

Referring to FIG. 13, an isolation layer 310, a resistance element 325, an insulation layer pattern 335, a contact 340, a conductive wire 350, and a first insulation interlayer 360 are formed on a semiconductor substrate 300. The insulation layer pattern 335 has a hole 33 formed therein. The contact 340 fills up the hole 33. The conductive wire 350 is formed on the contact 340 and the insulation layer pattern 335 such that the conductive wire 350 is connected to the contact 340. The first insulation interlayer 360 is formed on the insulation layer pattern 335 to cover the conductive wire 350.

Processes of forming the isolation layer 310, the resistance element 325, the insulation layer pattern 335, the contact 340, the conductive wire 350 and the first insulation interlayer 360 are substantially the same as processes in FIGS. 2 to 7. Thus, any further explanation will be omitted.

Referring to FIG. 14, a lower electrode 370a is formed on a portion of the first insulation interlayer 360 vertically corresponding to the resistance element 325. Although not particularly illustrated in FIG. 14, the lower electrode 370a can have a substantially plate shape.

To form the lower electrode 370a, a conductive layer is formed using a conductive material, such as a metal. A patterning process, such as a photolithography process, can be performed on the conductive layer to transform the conductive layer into the lower electrode 370a.

A dielectric layer 380 is formed on the first insulation interlayer 360 to cover the lower electrode 370a. The dielectric layer 380 can be formed using a material having a relatively high dielectric constant.

An upper electrode 370b is then formed on the dielectric layer 380. Particularly, the upper electrode 370b vertically corresponds to the lower electrode 370a. Although not particularly illustrated in FIG. 14, the upper electrode 370b can have a substantially plate shape.

To form the upper electrode 370b, a conductive layer is formed on the dielectric layer 380 by using a conductive material, such as a metal. A patterning process such as a photolithography process can then be performed on the conductive layer to transform the conductive layer into the upper electrode 370b.

As illustrated in FIG. 14, the dielectric layer 380 is formed between the lower and upper electrodes 370a and 370b that vertically correspond to each other. Thus, a capacitor is vertically formed.

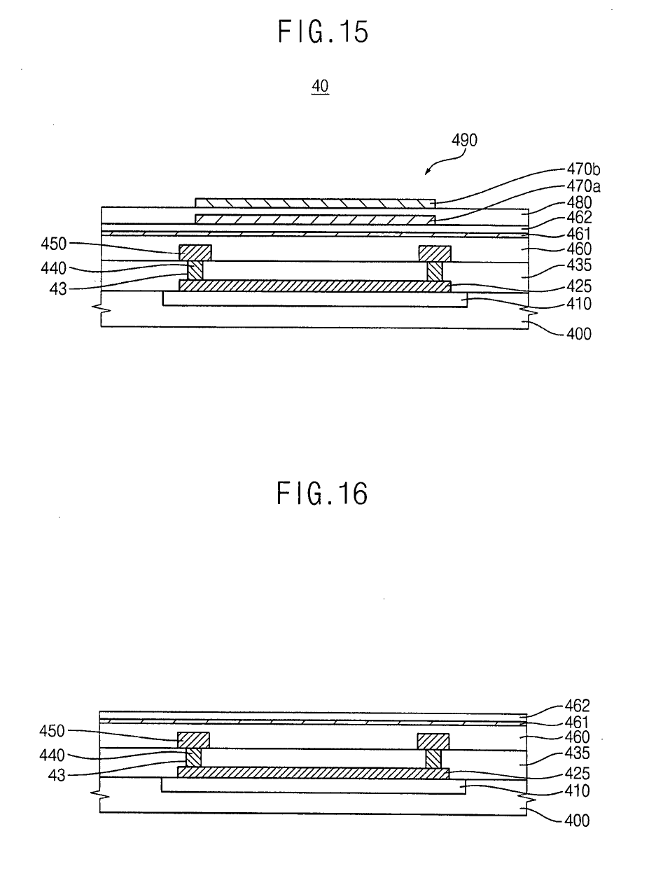

FIG. 15 is a cross-sectional view illustrating an embodiment of a semiconductor device in accordance with another aspect of the present invention.

Referring to FIG. 15, a semiconductor device 40 is substantially the same as the semiconductor device 20 in FIG. 9 except for a capacitor structure 490. Thus, a repetitive explanation will be omitted.

The capacitor structure 490 in the semiconductor device 40 is substantially the same as the capacitor structure 390 in FIG. 12. Thus, any further explanation will be omitted.

Hereinafter, an embodiment of a method of manufacturing the semiconductor device 40 in FIG. 15 is described.

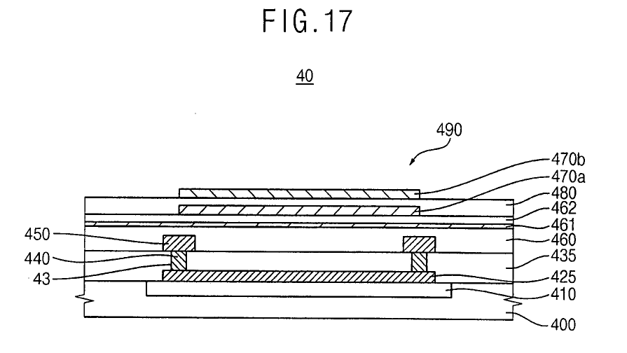

Specifically, FIGS. 16 and 17 are cross-sectional views illustrating a method of manufacturing a semiconductor device in FIG. 15.

Referring to FIG. 16, an isolation layer 410, a resistance element 425, an insulation layer pattern 435, a contact 440, a conductive wire 450, a first insulation interlayer 460, a protective layer 461, and a second insulation interlayer 462 are formed on a semiconductor substrate 400. The insulation layer pattern 435 has a hole 43 formed therein. The contact 440 fills up the hole 43. The conductive wire 450 is formed on the insulation layer 435 and the contact 440 such that the conductive wire 450 is connected to the contact 440. The first insulation interlayer 460 is formed on the insulation layer pattern 435 to cover the conductive wire 450.

Processes of forming the isolation layer 410, the resistance element 425, the insulation layer pattern 435, the contact 440, the conductive wire 450, the first insulation interlayer 460, the protective layer 461, and the second insulation interlayer 462 are substantially the same as processes in FIGS. 10 and 11. Thus, any further explanation will be omitted.

Referring to FIG. 17, a lower electrode 470a is formed on a portion of the second insulation interlayer 462 vertically corresponding to the resistance element 425. A dielectric layer 480 is then formed on the second insulation interlayer 462 to cover the lower electrode 470a. Thereafter, an upper electrode 470a is formed on the dielectric layer 480. Thus, a capacitor structure 490 including the lower electrode 470a, the dielectric layer 480, and the upper electrode 470b is formed.

According to the present invention, a space under a capacitor structure having a relatively wide area can be utilized for increasing an integration degree of a semiconductor device. Thus, the size of a semiconductor chip including the semiconductor device can be reduced.

In case that the size of the semiconductor chip is reduced, the number of semiconductor chips produced from one wafer can increase. Thus, the yield and productivity of the semiconductor chip can increase.

The foregoing is illustrative of the present invention and is not to be construed as limiting thereof. Although a few embodiments in accordance with the invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A semiconductor device comprising:
an electric element;
a first insulation interlayer provided on the electric element; and
a capacitor structure provided on the first insulation interlayer, the capacitor structure vertically disposed relative to the electric element and having a shape extending horizontally.

2. The semiconductor device of claim 1, wherein the electric element is a resistance element, a diode element, an inductor element, or a transistor element.

3. The semiconductor device of claim 1, further comprising:
a protective layer provided on the first insulation interlayer, the protective layer including a conductive material; and
a second insulation interlayer provided between the protective layer and the capacitor structure.

4. The semiconductor device of claim 3, wherein the protective layer is grounded.

5. The semiconductor device of claim 1, wherein the capacitor structure includes conductive structures, contact structures and an insulation structure, the conductive structures being spaced apart from one another in a first direction, the contact structures being provided on the conductive structures, the conductive structures and the contact structures being repeatedly stacked, and the insulation structure filling up spaces between the conductive structures and the contact structures.

6. The semiconductor device of claim 1, wherein the capacitor structure includes a lower electrode, a dielectric layer, and an upper electrode, the lower and upper electrodes having substantially plate shapes, the lower and upper electrodes vertically corresponding to each other, and the dielectric layer being provided between the lower and upper electrodes.

7. The semiconductor device of claim 1, wherein the electric element is a resistance element, the resistance element being provided on an isolation layer formed at an upper portion of a semiconductor substrate, and the resistance element including polysilicon being doped with impurities.

8. The semiconductor device of claim 7, further comprising:
an insulation layer pattern provided on the semiconductor substrate to cover the resistance element and the isolation layer, the insulation layer pattern having a hole exposing an end portion of the resistance element;
a contact provided in the hole; and
a conductive wire provided on the insulation layer pattern to be connected to the contact,
wherein the first insulation interlayer is provided on the insulation layer pattern to cover the conductive wire.

9. A method of manufacturing a semiconductor device, the method comprising:
forming an electric element;
forming a first insulation interlayer on the electric element; and
forming a capacitor structure on the first insulation interlayer, the capacitor structure vertically disposed relative to the electric element, and having a shape extending horizontally.

10. The method of claim 9, wherein the electric element is a resistance element, a diode element, an inductor element or a transistor element.

11. The method of claim 9, further comprising:
forming a protective layer on the first insulation interlayer by using a conductive material; and
forming a second insulation interlayer between the protective layer and the capacitor structure.

12. The method of claim 11, wherein the protective layer is grounded.

13. The method of claim 9, wherein the forming of the capacitor structure comprises:
forming conductive structures spaced apart from one another in a first direction;
forming a first insulation film between the conductive structures;
forming a second insulation film on the conductive structures and the first insulation films, the second insulation film having holes exposing the conductive structures; and
forming contact structures in the holes of the second insulation film;
wherein the forming of the conductive structures, the forming of the first insulation film, the forming of the second insulation film and the forming of the contact structures are repeatedly performed such that the conductive structures make vertical contact with the contact structures.

14. The method of claim 9, wherein the forming of the capacitor structure comprises:
forming a lower electrode having a substantially plate shape;
forming a dielectric layer on the lower electrode; and
forming an upper electrode on the dielectric layer, the upper electrode vertically corresponding to the lower electrode, and the upper electrode having a substantially plate shape.

15. The method of claim 9, wherein the electric element is a resistance element; and
wherein the forming of the electric element comprises:
forming an isolation layer at an upper portion of a semiconductor substrate;
forming a polysilicon layer doped with impurities on the isolation layer; and
transforming the polysilicon layer into the electric element on the isolation layer by performing a patterning process.

16. The method of claim 15, wherein the forming of the electric element comprises:
forming an insulation layer on the semiconductor substrate to cover the resistance element and the isolation layer;
forming a contact through the insulation layer to be electrically connected to an end portion of the resistance element; and
forming a conductive wire on the insulation layer to be connected to the contact;
wherein the first insulation interlayer is formed on the insulting layer pattern to cover the conductive wire.
